(19) United States
(12) Patent Application Publication
(10) Pub. No.: US 2025/0123319 A1
(43) Pub. Date: Apr. 17, 2025

(54) PROBE HEAD FOR LED TEST SYSTEM

(71) Applicant: Teradyne, Inc., North Reading, MA (US)

(72) Inventors: Frank Brian Parrish, Simi Valley, CA (US); Joseph Richard Arbuckle, Thousand Oaks, CA (US)

(21) Appl. No.: 18/380,934

(22) Filed: Oct. 17, 2023

(51) Int. Cl. G01R 31/26; G01R 1/067; G01R 1/30; G01R 19/145

(52) U.S. Cl. CPC G01R 31/2635; G01R 1/06761; G01R 1/30; G01R 19/145

(57) ABSTRACT

An example probe head includes probe needles that are electrically conductive and configured to create electrical connections to conductive pads on light emitting diodes (LEDs) on a wafer under test; power supplies to power the LEDs; multimeters to measure at least one of a voltage across or a current through individual ones of the LEDs; and micro-electromechanical (MEM) switches configured to create, for each of the LEDs, an electrical connection between ones of the probe needles and both a power supply and a multimeter to cause the power supply to power the LED while the multimeter measures the at least one of the voltage across or the current through the LED.

### TECHNICAL FIELD

This specification describes example implementations of a probe head and a test system that uses the probe head to test light emitting diodes (LEDs).

### BACKGROUND

A test system is configured to test the operation of a device. A device tested by the test system is referred to as a device under test (DUT). An example of a type of DUT that may be tested using a test system is a light emitting diode (LED). An LED is a semiconductor device that emits light when current flows through it. LEDs come in different sizes. For example, a micro-LED may be 1/100^{th} the size of a regular LED of about one to two millimeters in width or less, whereas a nano-LED may be still smaller than that. Micro-LEDs and nano-LEDs may be used, for example, to produce high-resolution displays for electronic devices. In general, the smaller an LED is, the more difficult it can be to test the LED and, in the case of large numbers of LEDs, the more time consuming it can be to test the LEDs.

### SUMMARY

An example probe head includes probe needles that are electrically conductive and configured to create electrical connections to conductive pads on light emitting diodes (LEDs) on a wafer under test; power supplies to power the LEDs; multimeters to measure at least one of a voltage across or a current through individual ones of the LEDs; and micro-electromechanical (MEM) switches configured to create, for each of the LEDs, an electrical connection between ones of the probe needles and both a power supply and a multimeter to cause the power supply to power the LED while the multimeter measures the at least one of the voltage across or the current through the LED. The example probe head may include one or more of the following features, either alone or in combination.

The probe head may include one or more processing devices to control operation of the MEM switches. The probe head may include one multimeter and one power supply for each of multiple sets of MEM switches. The MEM switches may be controllable to create electrical connection at a same time in each set of MEM switches. The MEM switches may be controllable to cycle through the MEM switches in each set so that, at a same time, an Nth (N≥1) MEM switch in each set creates an electrical connection between a probe needle and a power supply or a multimeter.

Each multimeter may include an analog-to-digital converter (ADC) and each power supply may include a digital-to-analog converter (DAC). The probe needles may be arranged on the probe head at an oblique angle relative to a surface of the probe head. The probe head may include electrically conductive traces electrically connected to the multimeters and a transceiver to interface between the electrically conductive traces and a communication conduit for connecting the probe head to an external device. The probe head may be or include a substrate, such as a circuit board or circuit card. The probe head may include a coupling attached to the substrate. The coupling may include a magnetically-attracted material. The coupling may include a metal plate. The coupling may include alignment pins to align to a structure that magnetically attracts the coupling. The probe head may include a flange configured for connection to a gripper. The LEDS may include micro-LEDs or nano-LEDs.

An example test system includes a light detector arranged above a test site containing a wafer containing LEDs to be tested by the test system, where the light detector is configured to detect light emitted from the LEDs; a probe head arranged above the wafer so as not to block a path of light between at least some of the LEDs and the light detector, where the probe head is configured to detect voltage across and current through individual ones of the LEDs; and a computing system configured to determine a quantum efficiency of each of individual ones of the LEDs, where the quantum efficiency of an LED is based on the light detected from the LED, the voltage across the LED, and the current through the LED. The probe head includes probe needles that are electrically conductive and configured to create electrical connections to the LEDs; power supplies to power the LEDs; multimeters to measure a voltage across, and current through, individual ones of the LEDs; and micro-electromechanical (MEM) switches configured to create, for each of the LEDs, an electrical connection between ones of the probe needles and both a power supply and a multimeter to cause the power supply to power the LED while the multimeter measures a voltage across, and a current through, the LED. The example test system includes one or more of the following features, either alone or in combination.

The test system may include a mount to hold the wafer containing the LEDs during testing and a motor to move the mount to cause the wafer to move relative to the probe head and the light detector in order to align successive sets of LEDs to the probe head and the light detector for testing. The test system may include a prober to hold the probe head during testing and a force gauge physically connected between the probe head and the prober. The force gauge may be configured to measure an amount of force applied by the probe needles to the wafer.

The probe head may include a substrate and a coupling attached to the substrate. The coupling may include a magnetically-attracted material. The test system further may include a magnet connected to the force gauge. The magnet may be configured to magnetically attract the coupling. The magnet may include an electromagnet that is controllable by the computing system to conduct current when the probe head is within a predefined proximity of the force gauge.

The system may include a robotic arm. The system may also include a detector to detect a magnetic connection to the force gauge. The detector may be configured to output a signal to the computing system in response to detecting the magnetic connection. The computing system may be configured to control the robotic arm, based on the signal from the detector, to move the wafer to or from a storage unit.

The probe head may include one or more processing devices to control operation of the MEM switches. The one or more processing devices may be in communication with the computing system to receive instructions from the computing system for controlling operation of the MEM switches. The probe head may include one multimeter and one power supply for each of multiple sets of MEM switches. The MEM switches may be controllable to create one electrical connection at a same time in each set of MEM switches. The MEM switches may be controllable to cycle through the MEM switches in each set so that, at a same time, an Nth (N≥1) MEM switch in each set of MEM switches creates an electrical connection between ones of the probe needles and both a power supply and a multimeter.

Each multimeter may include an analog-to-digital converter (ADC) and each power supply may include a digital-to-analog converter (DAC). The probe needles may be arranged on the probe head at an oblique angle relative to a surface of the probe head. The probe head may include electrically conductive traces electrically connected to the multimeters and a transceiver to interface between the electrically conductive traces and a communication conduit that is part of a communication connection between the probe head and the computing system. The LEDS may include micro-LEDs or nano-LEDs.

The probe head may include a device configured to communicate, to the computing system, information about the probe head. The device may include a memory. The information may include an identity or a condition of the probe head.

An example test system includes a probe head including probe needles that are electrically conductive and configured to create electrical connections to LEDs on a wafer under test; a structure configured to hold the probe head at an oblique angle relative to a test site containing the wafer under test, where the structure includes a cover that is movable between an open position and a closed position where, in the open position, a slot configured to hold the probe head is exposed and, in the closed position, the slot is covered; and robotics configured to move the probe head into, and out of, the slot. The example test system may include one or more of the following features, either alone or in combination.

The probe head may include first electrically conductive conduits and first electrical contacts. The first electrically conductive conduits may be between the probe needles and the first electrical contacts. The first electrical contacts may be at a first pitch. The test system further may include an interposer. The interposer may include second electrically conductive conduits and second electrical contacts. The second electrically conductive conduits may be electrically connected between the first electrical contacts and the second electrical contacts at a second pitch. The robotics may be configured to move the interposer into, and out of, the slot.

The test system may include a flexible circuit. The flexible circuit may include third electrically conductive conduits and third electrical contacts. The third electrically conductive conduits may be electrically connected between the second electrical contacts and the third electrical contacts. The third electrical contacts may be at a third pitch that is greater than the second pitch. The interposer may be a first interposer and the test system may include a second interposer. The second interposer may include fourth electrically conductive conduits and fourth electrical contacts. The fourth electrically conductive conduits may be electrically connected between the third electrical contacts and the fourth electrical contacts.

The test system may include one or more circuit cards including at least one of passive electronics or active electronics to process signals from the probe needles. The test system may include a backplane electrically connected to the second interposer. The backplane is configured to electrically connect the second interposer to one or more circuit cards. The backplane may include fifth electrically conductive conduits and fifth electrical contacts. The fifth electrically conductive conduits may be electrically connected between the fourth electrical contacts and the fifth electrical contacts. The fifth electrical contacts may be at a pitch that is greater than the third pitch.

Processing the signals may include determining whether LEDs associated with the probe needles passed or failed testing. The test system may include a test assembly including the structure and one or more motors or actuators to implement movement of the test assembly relative to the wafer. The one or more motors or actuators may be configured to at least one of: (i) rotate the test assembly relative to the wafer, or (ii) move the test assembly translationally relative to the wafer.

The test system may include a probe head, which may be a silicon wafer. The test assembly may be connected to the probe head and the probe head may be controlled by the motors. The cover may include a compression mechanism having a surface configured to contact a top of the probe head. The test system may include a light detector arranged above the test site containing the wafer under test, the light detector to detect light emitted from the LEDs.

Any two or more of the features described in this specification, including in this summary section, may be combined to form implementations not specifically described in this specification.

At least part of the devices, circuitry, systems, techniques, and processes described in this specification may be implemented or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, circuitry, systems, techniques, and processes described in this specification may be implemented or controlled using a computing system comprised of one or more processing devices and memory storing instructions that are executable by the one or more processing devices to perform various control operations. The devices, circuitry, systems, techniques, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIG. 1 is a block diagram showing a side view of an example test system for testing light emitting diodes (LEDs).

FIG. 2 is a front perspective view of components of the test system of FIG. 1.

FIG. 3 is a side view of an example probe head containing electrically-conductive needles on a surface thereof.

FIG. 4 is a block diagram showing a perspective view of an example probe head and components contained on the probe head.

FIG. 5 is a circuit diagram showing electrical connections made between an example probe head and LEDs during testing.

FIG. 6 is a block diagram showing an example configuration of miniature switches on an example probe head.

FIG. 7 is a flowchart showing operations included in an example process for testing LEDs using the probe head and the test system.

FIG. 8 is a block diagram showing a side view of an example test system for testing light emitting diodes (LEDs).

FIG. 9 is a block diagram showing a top view of an example probe head.

FIG. 10 is a diagram showing a perspective view of example mechanics for moving the probe head.

FIG. 11 is a side view of components for holding a probe head in the example test system of FIG. 8.

FIG. 12 is a perspective view of an example slot for holding a probe head and an interposer, and a cover therefor in a closed position.

FIG. 13 is a perspective view of an example slot for holding a probe head and an interposer, and a cover therefor in an open position.

FIG. 14 is a flowchart showing operations included in an example process for testing LEDs using the example test system of claim 8.

FIG. 15 shows example signal paths or circuit paths created between probe needles and a control system in the test system of FIG. 8.

Like reference numerals in different figures indicate like elements.

### DETAILED DESCRIPTION

Described herein are example implementations of a probe head configured to contact light emitting diodes (LEDs), including small form factor LEDs, and example implementations a test system configured to test the LEDs based on signals obtained using the probe head. Small form factor LEDs may include, but are not limited to, micro-LEDs and nano-LEDs. In some examples, a micro-LED has a size when viewed from above-for example, a footprint or outline—that is 500 square micrometers (μm²) or less, 400 μm² or less, 300 μm² or less, 200 μm² or less, 100 μm² or less, 75 μm² or less, 50 μm² or less, 40 μm² or less, 30 μm² or less, 20 μm² or less, 15 μm² or less, 10 μm² or less, 5 μm² or less, 4 μm² or less, 3 μm² or less, 2 μm² or less, or 1 μm² or less. Nano-LEDs can be smaller than micro-LEDs by one or more orders of magnitude. Accordingly, when used herein, the term “LED” may include, but is not limited, to nano-LEDs, micro-LEDs, LEDs that are larger than micro-LEDS, and various types of LEDs, such as organic LEDs (OLEDs) and others not listed.

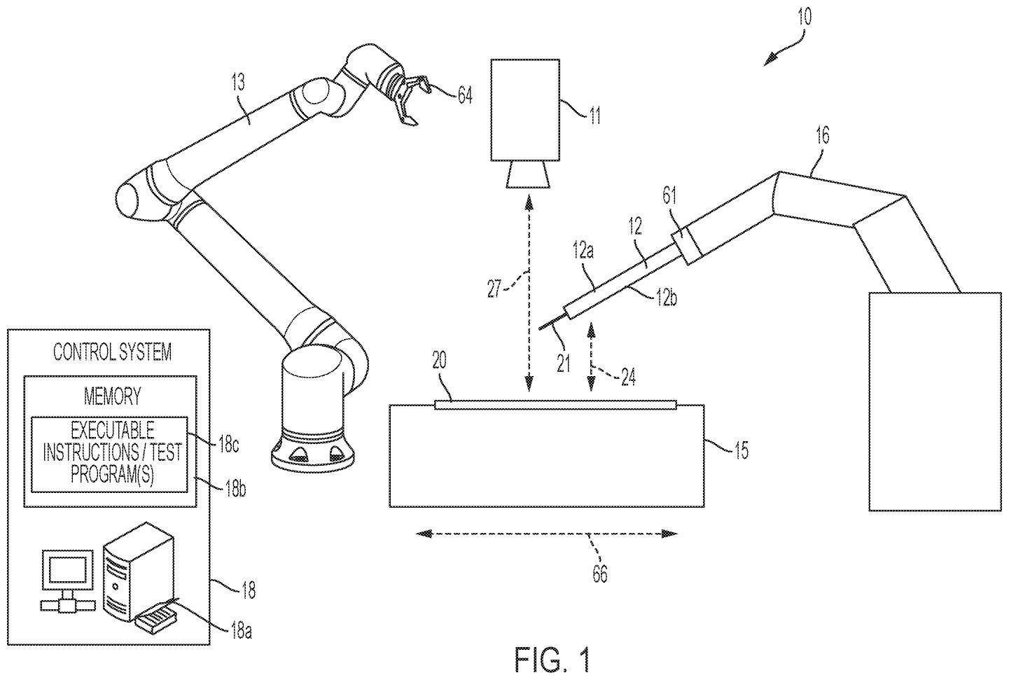

FIG. 1 shows a side view of an example test system 10 that includes a light detector 11, a probe head 12, a robotic arm 13, a mount 15, a prober 16, and a control system 18. Test system 10 operates as follows. Mount 15 is configured to hold a wafer 20 containing rows and columns of LEDs, such as micro-LEDs or nano-LEDs. Robotic arm 13 is controllable to pick-up probe card 12 and to mount probe card 12 on prober 16. Probe head 12 includes electrically conductive probe needles 21 (“needles”) to contact the LEDs. Prober 16, which may be a robotic arm like robotic arm 13 or other robotic device, is configured to move probe head 16 in the directions of arrow 24 to enable needles 21 on probe head 12 to contact LEDs on wafer 20. In some implementations, prober 16 may be a Sensapex® micromanipulator robot.

Probe needles 21 inject current into the LEDs which causes the LEDs to illuminate. Light detector 11 measures the illumination of the LEDs. Probe head 12 also includes current and voltage meters, such as a multimeter, to measure the voltage across and/or the current through each LED via needles 21.

The measured current and/or voltage and the measured illumination, for each LED are used to produce a test result for the LED. In some implementations, the current and/or voltage and the measured illumination are used to determine the quantum efficiency (QE) of the LED. The QE is a measure of the effectiveness of the LED to convert electrons into photons. In an example, if an LED has a QE of 100% and was exposed to 100 electrons of a signal, the LED would produce, for example, 100 photons or another appropriate number of photons designated to be a QE of 100%. Control system 18 compares the QE of each LED to a predefined threshold. LEDs that meet or exceed a predefined QE threshold pass testing. LEDs that have less than the predefined QE threshold fail testing. In some implementations, the LEDs can be binned (or ranked) into two or more bins based on values of their QEs. For example, if an LED has a QE in a first range, it is binned into a first bin; if an LED has a QE in a second range, it is binned into a second bin; if an LED has a QE in a third range, it is binned into a third bin; and so forth. In some implementations, only images from the light detector are evaluated for brightness and/or light frequency to determine how or where to bin the LEDs.

Control system may be a computing system having one or more processing devices 18a and memory 18b storing instructions 18c that are executable to control LED testing by controlling the hardware devices described herein.

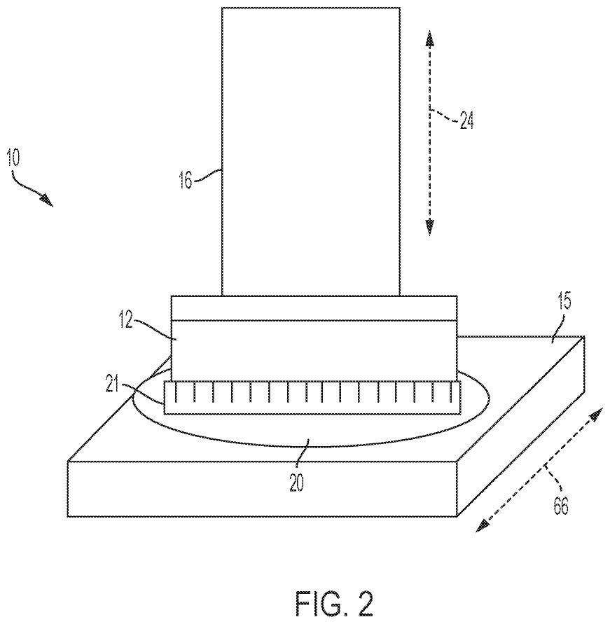

FIG. 2 shows a front perspective view of example probe head 12 having needles 21 in contact with LEDs on wafer 20. The probe head may be or include a circuit board or circuit card and, thus, may also be referred to as a probe card or probe board. In some implementations, the probe head may be or include a silicon wafer. The probe head may be formed on a substrate, such as FR-4, and may have a length/width form factor of 50 millimeters (mm) by 50 mm or greater. The probe head may weigh on the order of hundreds of grams in some implementations.

As noted above, probe head 12 includes probe needles (or simply “needles”) 21 on an edge/side or a surface of the probe head. The needles are electrically conductive and may be made of copper, gold, nickel, platinum, or any other electrically-conductive material. The needles may be arranged side-by-side in a linear array so that adjacent needles do not electrically touch each other. Adjacent needles may be held in place using a non-conductive substrate so that the adjacent needs to do not electrically touch each other. Needles 21, in this example, may be micro-needles since they are configured to contact, and thereby form an electrical connection with, electrical contacts on small-form-factor LEDs on a wafer. The cross-sectional area of each needle may be based on the size of the LEDs under test, with smaller cross-sections used for smaller LEDs, for example.

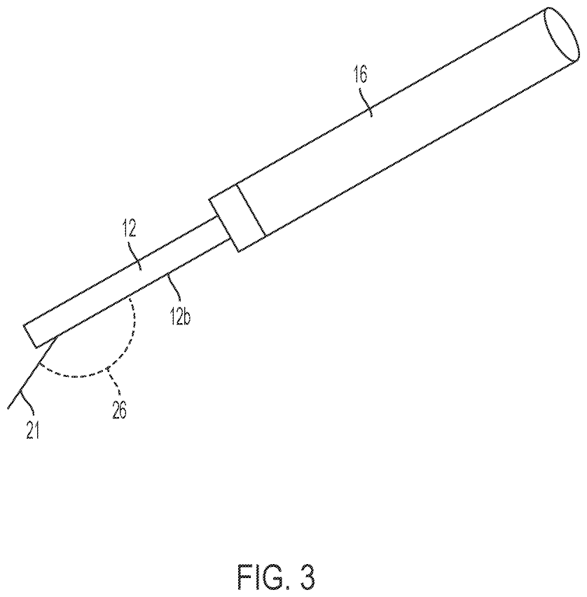

In implementations of the probe head where the needles are arranged on an edge like in FIG. 1, the needles may be parallel to the top surface and bottom surfaces 12a, 12b of the probe head, or at an oblique angle relative the top surface and bottom surfaces 12a, 12b of the probe head. An example implementation of probe head 12 where the needles are arranged on a surface 12b of probe head 12 is shown in FIG. 3. In the example of FIG. 3, needles 21 are at an oblique angle 26 relative to a surface 12a or 12b. Referring back to FIG. 1, needles 21 may be arranged in this manner (e.g., not at a 90° angle) to reduce the chances of the probe head blocking light detector 11 from receiving light from the LEDs. For example, the probe head 12, or a portion thereof, does not block an optical path 27 (see FIG. 1) between the LEDs under test on wafer 20 and light detector 11 or blocks an amount of the light that is small enough to still allow light detector 11 to detect light from the LED.

In some particular non-limiting examples, the LEDs may be produced by depositing flat layers of gallium-nitride (GaN) on a circular silicon wafer 20 having a diameter of 12 inches/30.48 centimeters (cm). An example 12-inch-diameter wafer may contain an one or more arrays of LEDs, each having a length of 10 millimeters (mm) or more or less. For example, there may be multiple sets of 10 mm arrays arranged linearly in rows and columns. Particularly in the case of micro-LEDs and nano-LEDs, the silicon wafer may contain thousands or millions of such LEDs arranged in rows and columns. Each row of LEDs may contain hundreds or thousands of LEDs. The edge/side of the probe head may correspond to the length of each row of LEDs, such as 10 mm or more in the preceding example.

The linear array of needles may contain hundreds or thousands of needles. Given the relatively small space to accommodate those needles, the needles themselves may have a cross-sectional area that is smaller than that of a human hair, e.g., 50 μm or less. Needles of this size can be easily damaged through bending or breakage. Accordingly, probe head 12 containing those needles may be handled by a robot, not manually, and may be attached to prober 16 magnetically, as described below.

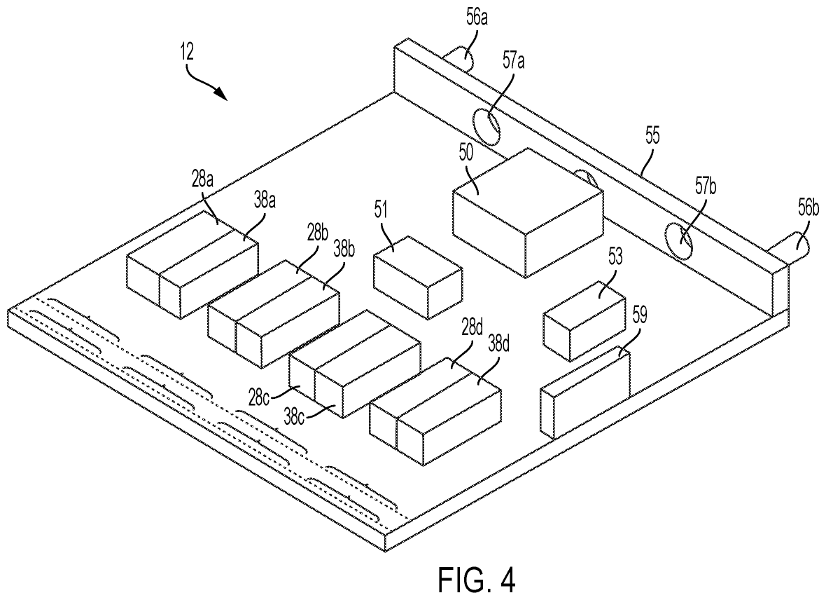

FIG. 4 is a perspective view of examples components on example probe head 12. Probe head 12 contains power supplies 28a to 28d to power the LEDs via the needles. Four power supplies are shown; however, probe head 12 may contain any appropriate number of power supplies. The power supplies may be voltage and/or current sources. In some implementations, each power supply may be or may include at least one a digital-to-analog converter (DAC), and each power supply may be in communication with control system 18 over one or more wired and/or wireless communication links. Connections to the control system may run through prober 16. Control system 18 may be configured to provide a digital signal to a DAC, which digital signal is indicative of a voltage or current to apply to a LED. The DAC is configured to convert this digital signal into an analog voltage or current that is provided to power a LED via two needles 21.

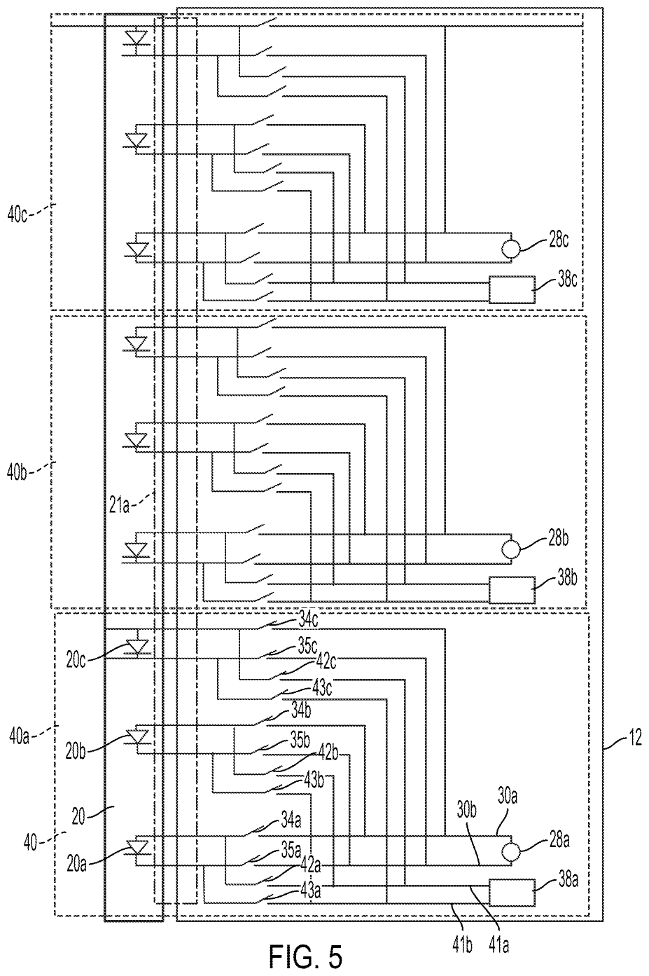

A single DAC may provide power to test multiple LEDs. Referring to FIG. 5, that figure shows example electrical connections between probe head 12 and LEDs under test created by moving the needles into contact with conductive terminals of the LEDs' anodes and cathodes. Needles 21 are referred to collectively using the enclosed dashed box 21a. Components 40 of probe head 12 enable the LED testing.

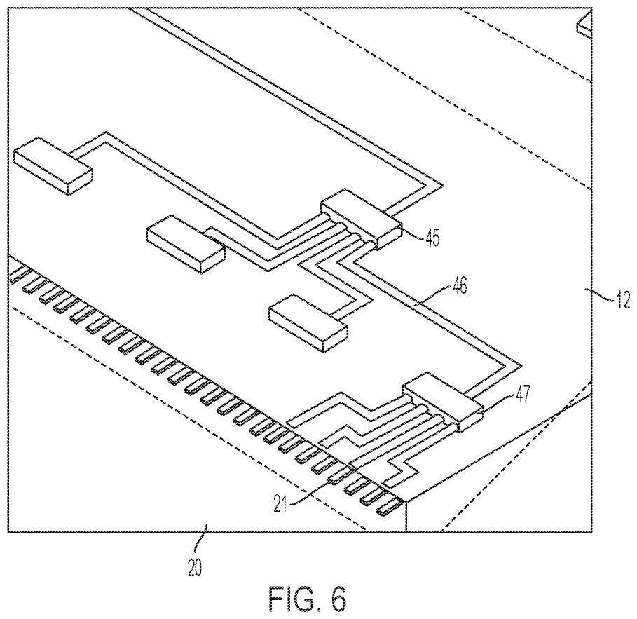

FIG. 5 shows components 40 repeated three times as 40a, 40b, 40c. However, components 40, or any appropriate variant thereof, may be repeated any number of times on the probe head. Furthermore, FIG. 5 shows a power supply and multimeter that are connectable to three LEDS. In other implementations of components 40, a power supply and multimeter may be connectable to fewer than three LEDs or to more than three LEDs. Still further, FIG. 5 shows a single layer of switches to make connections between the probe head and the LEDs. In some implementations of components 40, there may be multiple layers of switches used to make the connections. For example, a switch may enable connection to multiple branches, each containing a switch. An example of this configuration is shown in FIG. 6. In this example, switch(s) 45 are controllable to select a branch 46. Switch(es) 47 in branch 46 are controllable to make the final connection to the LEDs described with respect to FIG. 5.

As shown in FIG. 5 shows, DAC 28a connects to force (F) line 30a for providing current to LEDs 20a 20b, 20c, and connects to return (R) line 30b that acts as a return path for the current. Force line 30a could provide a positive or negative current with respect to the return line. Force line 30a is electrically connectable to LEDs 20a, 20b, 20c via respective switches 34a, 34b, 34c; and return line 30b is electrically connectable to the same LEDs 20a, 20b, 20c as the force line via respective switches 35a, 35b, 35c. For example, to power LED 20a, switch 34a is controlled to connect force line 30a to the anode of LED 20a and switch 35 is controlled to connect return line 30b to the cathode of LED 20a. The switches may be controlled by control system 18 based on a test program executed by the control system to test a set of LEDs.

Referring back to FIG. 4, probe head 12 contains voltage and current meters, such as multimeters 38a to 38d, to measure a voltage across and/or a current through individual ones of the LEDs. In some implementations, each multimeter may be, or may include, at least one analog-to-digital converter (ADC), and each multimeter may be in communication with control system 18 over one or more wired and/or wireless communication links, which may run through prober 16. For example, a multimeter may measure the current through and/or voltage across an LED via needles on the probe head, and report values of the current and/or voltage to control system 18. The ADC may be configured to convert analog voltage and current values obtained via the needles to digital values and to send those digital signals to control system 18.

A single ADC may measure voltage and/or current for multiple LEDs. For example, FIG. 5 shows that force sense line 41a connected to ADC 38a is electrically connectable to different LEDs 20a, 20b, 20c via respective switches 42a, 42b, 42c; and return sense line 41b is electrically connectable to the same LEDs 20a, 20b, 20c as force sense line 41a via respective switches 43a, 43b, 43c. In this example configuration, to measure current through and/or the voltage across LED 20a, switch 42a is controlled to connect force sense line 41a to the anode of LED 20a and switch 43a is controlled to connect return sense line 42b to the cathode of LED 20a. These connections are then broken and similar connections are made to LED 20b, and so forth. The switches may be controlled by control system 18 based on a test program executed by the control system to test a set of LEDs.

To test a single LED, such as LED 20a, all four corresponding switches 34a, 35a, 42a, 43a are closed at the same time. In a particular example, the set of switches is controllable (i) to close and thereby create a Kelvin connection as close as possible to a respective needle 21 that provides power to the anode of a respective LED and that functions as a sense line for the same LED, and (ii) to close to create a Kelvin connection as close as possible to a needle that functions as a return from the cathode of the same LED and that functions as a sense return line for the same LED. An example Kelvin connection is a electrical connection with a LED that is made in a way that eliminates or reduces effects of contact resistance. A Kelvin connection may be made using a four terminal device in which two terminals (34a, 35a) conduct current, while the other two terminals (42a, 43a) are used to measure voltage and current.

As shown in FIG. 5, there may be several multimeters on a probe head that are connectable to different sets of LEDs during testing. In some implementations, there may be one multimeter and one power supply for each respective set of LEDs that together, measure and power, respectively, each LED in the set. In some implementations, the return and return sense lines may be electrically connected to attach to a common electrically conductive return plane that attaches to each of the LEDs' cathodes via a corresponding needle.

In some implementations, the switches described herein, such as switches 34a to 34c, 35a to 35c, 42a to 42c, and 43a to 43c, that are controllable to connect the power supplies and multimeters to different LEDs may be or include micro-electromechanical (MEM) switches. In an example, MEM switches may be or include miniaturized mechanical and/or electro-mechanical structures that are made using microfabrication techniques. In some examples, when viewed from above—e.g., a footprint or outline—of a MEM switch can vary from one square micron or less than one square micron up to several square millimeters or more; although the MEM switches described herein are not limited to these example dimensions. The sizes of the MEM switches used on the example probe heads described herein may be based on the sizes and numbers of LEDs on a wafer. For example, the smaller that the LEDS on a wafer are, and the greater their numbers, the more MEM switches may be needed and, therefore, the smaller those MEM switches may be. Conversely, the larger that the LEDS on a wafer are, and the fewer their numbers, the fewer MEM switches may be needed and, therefore, the larger those MEM switches may be.

To summarize, the MEM switches are configured and controllable to create, for each of the LEDs under test, an electrical connection between two of the probe needles (one needle connects to the cathode of the LED and one needle connects to the anode of the LED) and both a power supply and a multimeter to enable the power supply to power the LED while the multimeter measures a voltage across and/or the current through the LED. As noted above, the MEM switches may be controlled by control system 18 based on a test program executed by the control system to a set of LEDs such as LEDs 20a to 20c. The MEM switches may be is in communication with control system 18 over one or more wired and/or wireless communication links. The one or more wired and/or wireless communication links may run through prober 16.

The control system may control sets of MEM switches by cycling through the MEM switches so that an Nth (N≥1) set of MEM switches in each of multiple groups of MEM switches create electrical connections between a probe needle and both a power supply and a multimeter. In this regard, in the example of FIG. 5, there are three sets of MEM switches in each instance 40a, 40b, 40c of components 40: for example, first set 34a, 35a, 42a, 43a; second set 34b, 35b, 42b, 43b; and third set 34c, 35c, 42c, 43c. During testing, the same set of switches in each instance of components 40 (e.g., 40a, 40b, 40c) are closed, and the other two sets are open. As a result, in this example, only every third LED is illuminated during testing. Adjacent LEDs, therefore, are not illuminated during testing. Cycling testing of the MEM switches in this manner reduces or eliminates the chances that adjacent LEDS will be illuminated, which can complicate testing, particularly if the light detector is not sensitive enough to distinguish between light from adjacent LEDs, for example, because those two LEDs are close together.

The MEM switches may be controlled in this manner to test the first LED in each set, then the second LED in each set, and so forth until all LEDs in each set are tested. The order of testing need not be sequential; the LEDs may be tested in any order.

Referring back to FIG. 4, probe head 12 contains electrically conductive traces (not shown) to provide electrical connections among the power supplies, the multimeters, the MEM switches, the needles, and other components.

Probe head 12 may contain a transceiver 50 configured to interface between the electrically conductive traces and one or more communication conduits, which may run through prober 16, for connecting probe head 12 to an external device, such as control system 18. For example, control system 18 may communicate with probe head 12 over one or more fiber optic cables (an example of the communication conduit). In this example, transceiver 50 converts between electrical and optical signals to enable the communication between the probe head and control system 18. In other examples, control system 18 may communicate with probe head 12 over a one or more data buses (an example of the communication conduit). Transceiver 50 may format communications for output to the data bus(es) and format transmissions from the data bus for output to the conductive traces. By using MEM switches on the probe head configured as described herein, fewer communication conduits may be needed to the probe head, since the MEM switches may route signals on the probe head.

Circuitry 51 may be electrically connected to transceiver 50 via one or more of the conductive traces and may be controllable to route signals between the transceiver and the power supplies and/or the multimeters. In some implementations, circuitry 51 may include one or more multiplexers and/or switches (not shown). In some implementations, circuitry 51 may be configured to control DAC(s), ADC(s), and/or switches and to route data to and from transceiver 50.

Probe head 12 may contain a device configured to communicate or to provide, to control system 18, information about the probe head. For example, probe head 12 may contain memory 53, which may be implemented using one or more memory devices such as non-volatile random access memory (NVRAM). The memory may store information such an identity of the probe head or a condition of the probe head. For example, the identity and condition information may include, but is not limited to, probe head part number, manufacture date, specifics on voltage and current for LEDs to be tested by the probe head, calibration data, size and style of the needles, the number of touchdowns implemented by the probe head, overdrive force, and the like. Data can be written and read back to the host computer through a data port on the memory. Other information unrelated to an identity or condition of the probe head may also be stored in the memory. The control system may access the memory via circuitry 51 and electrically conductive trace(s) between circuitry 51 and memory 53. The control system may read information such as, but not limited to, that described herein from the memory and write information to the memory, such as updating the number of tests performed using the probe head.

The communication connection between the probe head and the control system may be through prober 16 as noted, and may be implemented using one or more blind mate connectors. For example, a first blind mate connector may supply power from an external power supply to power electronic parts on the probe head. A second blind mate connector may be or include a bi-directional data connector to the control system. This connector may be a traditional copper wire connector supporting universal serial bus (USB), serial peripheral interface (SPI) bus or other common control busses. Alternately, this data connector may be high speed flexible optical interface.

The blind mate connectors may be part of a magnetic coupling structure, such as plate 55. Plate 55 may be made out of any appropriate ferromagnetic material, such as iron or nickel. Plate 55 may also contain alignment pins 56a, 56b to align to corresponding holes in prober 16 and alignment holes 57a, 57b to receive alignment pins of the prober. The alignment pins may be coarse alignment features and the alignment holes may be fine alignment features. The coarse alignment feature require less precision to achieve alignment than the fine alignment features. Plate 55 may also contain a flange 59 configured for connection to a gripper.

Referring to FIG. 1, prober 16 includes a connection interface 61 to receive and to hold probe head 12. Prober 16 is configured, and controllable by control system 18, to move probe head relative to a wafer on mount 15 to cause needles on the probe head to come into contact with lines of LEDs on the wafer to create the electrical connections described previously. The connection interface may include a force gauge physically connected between the end of prober 16 and a probe head held by prober 16. The force gauge is configured to measure a measure an amount of force of the probe needles against the wafer and to provide that measurement to the control system. The control system may then control prober 16 to increase or to decrease the amount of force. For example, if the force is too great, the probe needles may be damaged. In the event that the force is too great, the probe may be controlled to reduce the amount of force and thereby potentially avoid damage to the needles and the wafer.

Connection interface 61 may be, or include, a magnetic material, such as a rare earth magnet (e.g., a neodymium magnet or a samarium-cobalt magnet), or an electromagnet configured to generate magnetic force through conduction of current proximate to a ferromagnetic material. For example, the electromagnet may be controllable by the control system to conduct current when the probe head is within a predefined proximity of the force gauge. Connection interface 61 may also include alignment holes that correspond to the locations of alignment pins on plate 55 and alignment pins that correspond to the locations of alignment holes on plate 55. Connection interface 61 may also, or alternatively, include a mechanical clamp mechanism which is operated by pneumatic cylinders or small electric motors, and which holds the probe head in place.

Probe head 12 may be installed on prober 16 using robotic arm 13. Robotic arm 13 may include a gripper 64 at a tool flange thereof to pick-up probe head 12 via flange 59 (FIG. 4). Alternatively, robotic arm 13 may include a magnetic material and flange 59 may be made of a ferromagnetic material such that a magnetic attraction is used to pick-up the flange. Picking-up probe head 12 via flange 59 may reduce the chances of damage to the needles. The robotic arm may pick-up the probe head from a storage unit, for example. The robotic arm may bring plate 55 into proximity of connection interface 61 so that the alignment pins 56a, 56b on plate 55 align to complementary alignment holes on connection interface 61. The resulting magnetic attraction between plate 55 and connection interface 61 moves the two into connection and holds plate 55, and thus probe head 12, to the prober. Following testing the robot may remove the probe head from connection interface 61. For example, the robot may apply sufficient pulling force via gripper 64 and flange 59 to overcome the magnetic attraction of plate 55 and connection interface 61, or current to an electromagnet at connection interface may cease thereby enabling the robot to remove the probe head using relatively little force and replace it in a storage unit, for example.

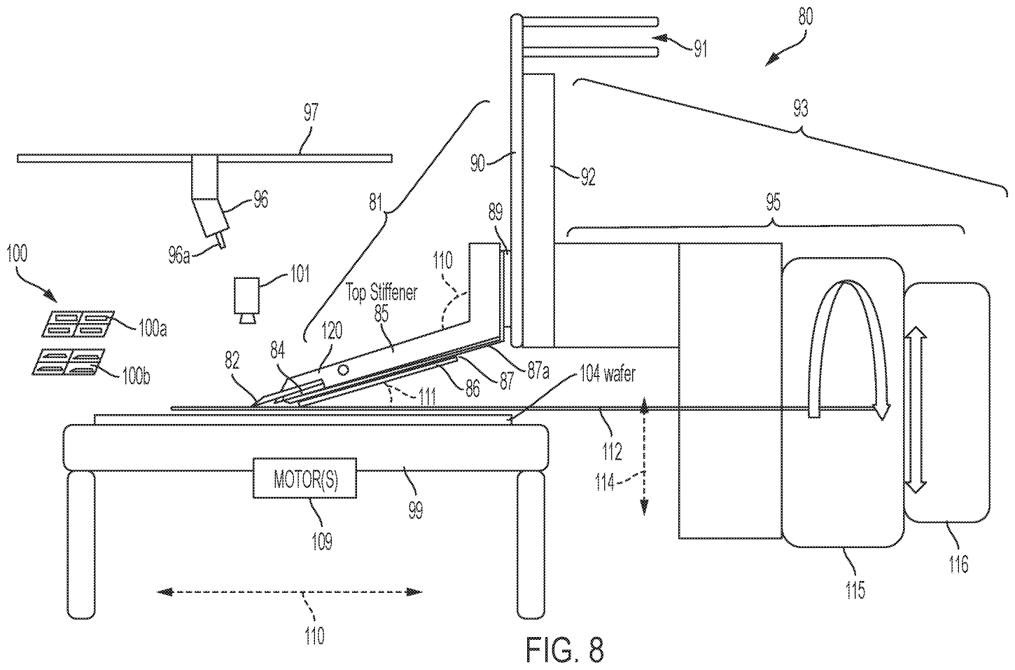

In some implementations, a gantry-mounted robotic arm like that shown in FIG. 8 (described below) may be used instead of robotic arm 13. In such implementations, the gantry-mounted robotic arm may include a gripper like gripper 64 to pick-and-place the probe head. In some implementations, the robotic arm may move along the gantry in two dimensions or in three dimensions to position the robotic arm relative to the prober.

In some implementations, the blind mate connectors described previously contain a precision magnetically attractive bracket, which is another implementation of the magnetic coupling describe previously. This magnetically attractive bracket contains both course and find alignment features, such as the holes and pins described above, that correspond to complementary mating feature on prober 16. As the probe head moves into the fine alignment features, all of the blind mate connectors begin to mate. An electromagnet, such as that described above, clamps the probe head in place. One or more electrical signals may be generated in response to the connection between the probe head and the prober, which may provide confirmation to control system 18 that the probe is attached to the prober properly.

As shown in FIGS. 1 and 2, test system 10 includes mount 15 to hold wafer 20 during testing. Mount 15 may include one or more motors that are controllable to move the mount to cause the wafer to move relative to probe head 12 and light detector 11 in the directions of arrow 66 and/or in a direction perpendicular to arrow 66 in order to align successive sets of LEDs to the needles on probe head 12 and to light detector 11 for testing. Accordingly, in this example, during testing, the probe head remains stationary while the wafer moves. In some implementations, prober 16 may move the probe head in the directions of arrow 66 and/or in a direction perpendicular to arrow 66 and the wafer may remain stationary.

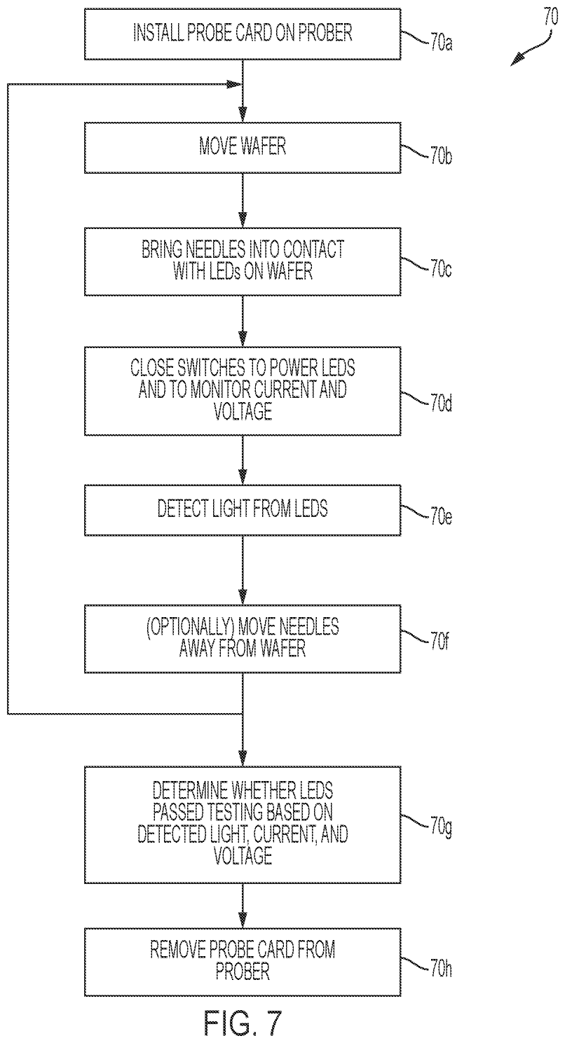

FIG. 7 shows an example process 70 for performing testing using probe head 12 and test system 10. Process 70 may be performed using the various devices shown in FIG. 1 and may be controlled, in whole or in part, by control system 18.

Process 70 includes installing (70a) probe head 12 onto the connection interface 61 of prober 16. This may be done by robotic arm 13 to pick-up probe head 12 via flange 59 and bringing plate 55 into proximity of connection interface 61 of prober 16. Magnetic attraction between plate 55 and connection interface 61 creates a physical connection between the two, which is maintained throughout testing. The alignment pins and holes described above ensure proper alignment.

Wafer 20 containing LEDs to test is moved (70b) into position by moving mount 15, e.g., in a direction of arrow 66. Prober 16 moves probe head into contact with wafer 20, as shown in FIG. 2 for example, so that needles 21 on the probe head contact (70c) LED anode and cathode terminals on the wafer and create electrical connections to each LED, as described with respect to FIG. 5 for example. The MEM switches on probe head are selectively controlled to close (70d) to create electrical connections between the power supplies and multimeters on the probe head and LEDS via the needles. As described above, sets of MEM switches may be selectively closed so that adjacent LEDs are not illuminated during testing. During testing, each LED may be turned on and then off at a specific programmed rate by increasing applied current over time. The amount of current and voltage applied over time may be captured to create a voltage-current (V-I) curve for each LED that is tested. Data for the V-I curve may be transmitted to a control system. In some implementations, the probe head may contain one or more processing devices (not shown) to create the V-I curve on the probe head and to transmit the V-I curve to the control system. Also, while each LED is illuminated, light detector 11 detects (70e) the light and reports the detected information to the control system along with an indication of which LED was illuminated.

Once test information has been obtained from a linear array of LEDs, prober 16 may be controlled to move away (70f) from wafer 20. This operation is optional and, in some implementations, prober 16 does not move. Thereafter, operations 70b to 70f may be repeated until test data is obtained for all LEDs on the wafer. After test data has been obtained, control system 18 analyzes the test data as described above to determine (70g) which LEDs pass testing and which LEDs failed testing. After testing is completed, probe head 12 may be removed (70h) from prober 16 as described herein.

FIG. 8 shows another example of a test system 80 for testing LEDs such as the LEDs described herein. The system of FIG. 8 moves electronics off of the probe head, thereby allowing for a probe head having a relatively small form factor to be used.

Examples of components in test system 80 include a test assembly 81 comprised of probe head 82, interposer 84, stiffeners 85 and 86, flexible circuit 87, interposer 89, backplane 90, and circuit cards 91. Examples of components in test system also include test head 93, mechanics 95, pick-and-place robotics (robot) 96, gantry 97, chuck 99, trays 100, and light detector 101.

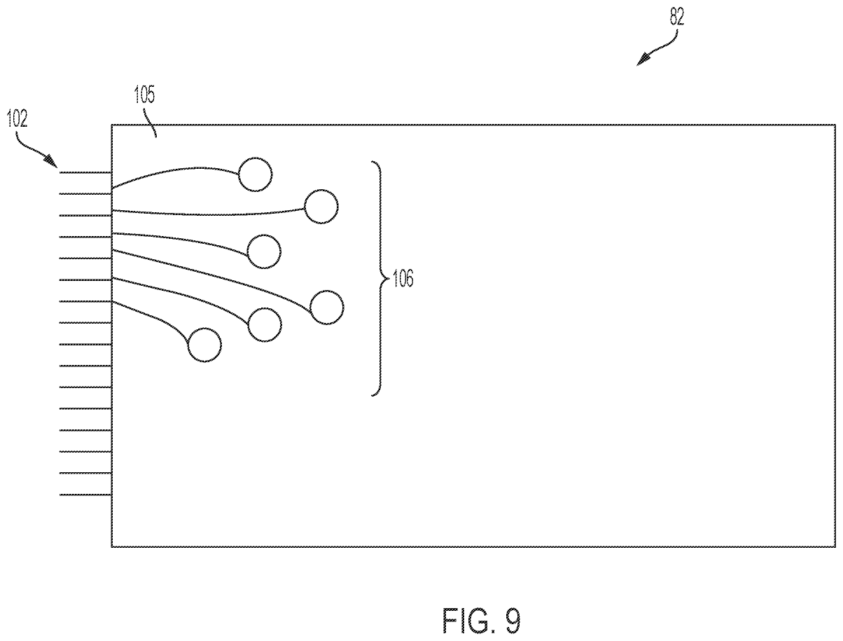

As shown in FIG. 9, probe head 82 includes needles 102 having the same structure and function as needles 21 described herein. Specifically, needles 102 contact LEDs under test on wafer 104 (FIG. 8), which may have a same configuration as wafer 20 described herein, such that a first needle electrically connects the force line of a voltage source to the anode of an LED and a second needle, which is adjacent to the first needle, electrically connects the return line of the voltage source to the cathode of the same LED. In this configuration, using pairs of needles, current may be applied to each LED for testing as described herein with respect to FIG. 5 and voltage across and/or current through individual ones of the LEDs may be measured.

In this example, probe head 82 may be made of silicon and may have a relatively small length/width form factor such as 4 mm by 6 mm, 5 mm by 10 mm, 10 mm by 10 mm, 15 mm by 20 mm, 15 mm by 20 mm, 15 mm by 30 mm, and so forth. Probe head 82 may be relatively light in weight, weighing, for example, less than 1 gram (g) to tens of grams, e.g., 0.25 g, 1 g, 1.5 g, 2 g, 3 g, 10 g, 20 g, and so forth. Probe head 82 may also be disposable and low in cost, costing around US $10 per probe head.

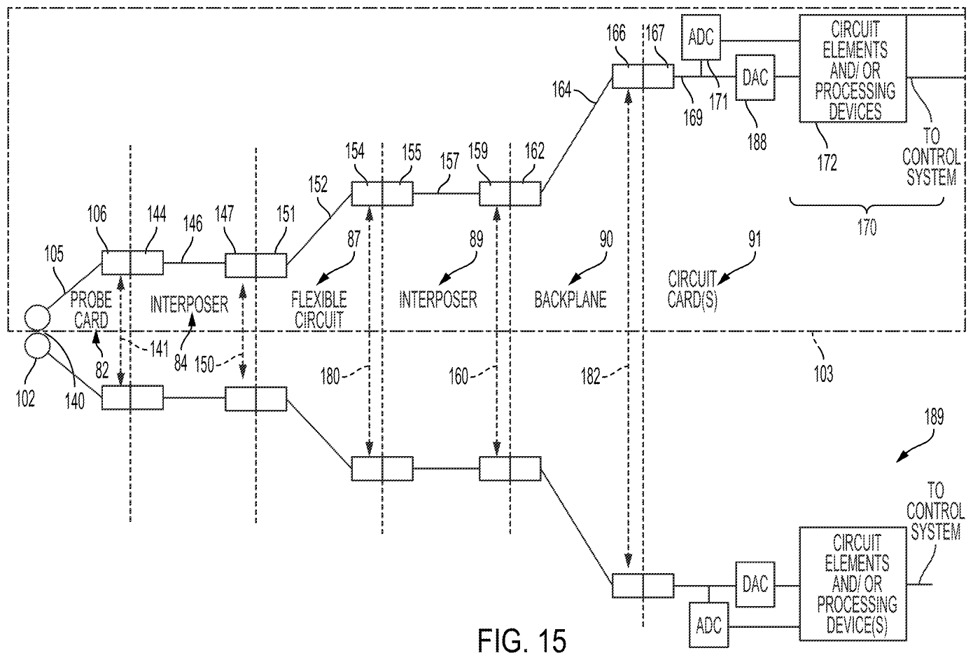

FIG. 15 shows two example needles 102 and two example electrical paths or circuit paths between those two needles and a control system such as control system 18 described herein. The electrical paths or circuit paths between each needle and the control system may each have a similar or identical construction; accordingly, only electrical path/circuit path 103 of FIG. 15 is described. As indicated above, in some implementations, there may be hundreds or thousands of such needles and electrical paths or circuit paths included in test system 80. The structure of the circuit paths shown FIG. 15 applies to any two adjacent needles on probe head 82.

As shown in FIGS. 9 and 15, probe head 82 includes electrically conductive conduits 105, such as metal traces, (shown for only a subset of needles 102 in FIG. 8) electrically connected to corresponding needles 102. Each electrically conductive conduit 105 is connected to a corresponding electrically conductive pad 106 on the probe head to form an electrical signal path or circuit path. The electrically conductive conduits 105 may be configured, as shown in FIGS. 9 and 15, so that the pitch of the electrically conductive pads 106 is greater than the pitch of needles 102. The pitch includes the distance between adjacent electrical contacts, needles, or signal paths. In the example shown in FIG. 15, the pitch between needles 102 is labeled 140 and the pitch between electrically conductive pads 106 is labeled 141. In some implementations, pitch 141 of adjacent electrical contacts 106 may be larger than pitch 140 of adjacent needles by a factor of 2, 3, 4, 5, 6, 7, 8, 9, 10 or more.

Also referring back to FIG. 8, electrically conductive pads 106 are connected electrically to an interposer 84. An example interposer includes a device containing electrically conductive conduits that pass electrical signal paths between one part of the interposer and another part of the interposer. Referring to FIG. 15, in this example, interposer 84 includes first electrical contacts 144, each connected to a conductive pad 106 on probe head 82 and to one or more electrically conductive conduits 147 within the interposer. Electrically conductive conduits 144 in interposer 84 are also connected to second electrical contacts 147 on another part (e.g., an output) of interposer 84, such that signals from respective ones of first electrical contacts 144 are transmitted to respective ones of second electrical contacts 147. In this example, second electrical contacts 144 have a pitch 150 that is the same as pitch 144 of first electrical contacts 144. Interposer 84 can thus be said to maintain the pitch of the signal paths. In some implementations, interposer 84 may change the pitch—for example increase the pitch such that pitch 150 is greater than pitch 141. In some implementations (not shown), interposer 84 may increase pitch 150 by a factor of 2, 3, 4, 5, 6, 7, 8, 9, 10 or more.

Referring also to FIG. 8, flexible circuit 87 electrically connects interposer 84, and thus probe head 82, with backplane 90. To this end, flexible circuit 87 includes first electrical contacts 151 connected to second respective electrical contacts 147 on interposer 84 and to electrically conductive conduits 152 in the flexible circuit. The electrically conductive conduits 152 in flexible circuit 87 are also connected to second electrical contacts 154 on another part of the flexible circuit adjacent to interposer 89, such that signals from respective ones of first electrical contacts 151 are transmitted to respective ones of second electrical contacts 154. In some implementations, flexible circuit 87 changes—for example, increases—the pitch of the signal paths. For example, In some implementations, flexible circuit may increase pitch 150 by a factor of 2, 3, 4, 5, 6, 7, 8, 9, 10 or more to produce pitch 180. In some implementations (not shown), flexible circuit 87 may maintain—that is, not change—the pitch of the signal paths.

In some implementations, another interposer 89 electrically connects flexible circuit 87 with backplane 90, as shown in FIGS. 8 and 15. In this example, interposer 89 includes first electrical contacts 155, each connected to a corresponding second electrical contact 154 on flexible circuit 87 and to one or more electrically conductive conduits 157 in interposer 89. Electrically conductive conduits 157 in interposer 89 are also connected to second electrical contacts 159 on another part (e.g., the output) of interposer 89, such that signals from respective ones of first electrical contacts 155 are transmitted to respective ones of second electrical contacts 159. In this example, second electrical contacts 159 have a pitch 160 that is the same as pitch 180 of first electrical contacts 155. In some implementations (not shown), second interposer 89 may increase pitch 180 by a factor of 2, 3, 4, 5, 6, 7, 8, 9, 10 or more.

Second electrical contacts 159 on interposer 89 are connected to corresponding electrical contacts 162 on backplane 90. So, in this example, probe head 82, interposer 84, flexible circuit 87, and interposer 89, create an electrical signal path or circuit path between needles 102 and backplane 90, over which signals from LEDs may pass between the backplane and the LEDs.

Backplane 90 includes first electrical contacts 162 connected to each second respective electrical contact 159 on interposer 89 and to one or more electrically conductive conduits 164 in backplane 90. The electrically conductive conduits in the backplane are also connected to second electrical contacts 166 on another part of the backplane, such that signals from respective ones of first electrical contacts 162 are transmitted to respective ones of second electrical contacts 166. In some implementations, backplane 90 changes—for example, increases—pitch 160 of the signal path to pitch 182, as shown in the example of FIG. 15. In implementations where the backplane increases the pitch, the backplane may increase pitch 160 by a factor of 2, 3, 4, 5, 6, 7, 8, 9, 10 or more. In some implementations (not shown), backplane 90 maintains pitch 160 such that pitch 160 and pitch 182 are substantially the same.

Backplane 90 includes second electrical contacts 166 that are connected electrically to respective electrical contacts 167 on a circuit card 91. Circuit cards 91 each includes electrically conductive conduits 169 connected to respective electrical contacts 167. The circuit cards 91 may connect to second electrical contacts 166 of backplane 90 through corresponding slots in the backplane. Although two circuit cards 91 are shown in FIG. 8, test system 80 may contain fewer than two or more than two—for example, three, four, five, and so forth—circuit cards connected to backplane 90.

In some implementations, backplane 90 may include switches such as the MEM switches included in FIG. 4 to route signals to and from the needles. In some implementations, the electronic components described with respect to FIG. 4 may be included on backplane 90 and/or circuit cards 91. These electronic components may have the same functions described with respect to the implementation of FIGS. 1 to 7.

In the example configuration of FIG. 9, there is an electrical connection among needles 102, probe head 82, interposer 84, flexible circuit 87, interposer 90, backplane 90, and circuit boards 91. Electrical signals—for example, analog measurements of voltage at, and current through, LEDs on wafer 104—can pass from needles 102 to circuit cards 91 over this electrical connection. Current to power the LEDs may pass from circuit cards 91 to needles 102 over this electrical connection.

In some implementations, circuit cards 91 may include passive and/or active electronics 170 (FIG. 15) for converting and/or processing the electrical signals. For example, in some implementation, circuit cards 91 may each include one or more analog-to-digital converters (ADC) 171 along each of its electrically conductive conduits 169 to convert respective analog measurements of LEDs on wafer 104 into digital signals as described herein. For example, in some implementation, circuit cards 91 may each include one or more digital-to-analog converters (DAC) 188 along each of its electrically conductive conduits 169 to provide power to the needles and thus the LEDs as described herein. In some implementation, circuit cards 91 may each include one or more multiplexers (not shown) along its electrically conductive conduits 169 to route the resulting digital signals to one or more processing devices 172 of the type described herein for analysis. In some implementation, circuit cards 91 may each include the one or more processing devices 172 (as shown in FIG. 15) to determine whether the LEDs passed or failed testing based on voltage and/or current measurements from needles 102 and detected light as described herein. In some implementations, the one or more processing devices may be in a control system, such as control system 18, in communication with a circuit card 91. The control system may receive digital signals from one or more circuit cards 91 for processing. In some implementations, circuit cards 91 may each include other circuit elements, such as digital-to analog converters

(DACs) (not shown) to convert the digital signals back into analog signals for further processing and/or measurement. In some implementations, circuit cards 91 may each include buffer(s), relays(s), capacitor(s), resistor(s), or other circuit elements 172 in each of their electrically conductive conduits 169 to change, delay, and/or route the analog measurements of LEDs or digitized versions thereof.

In some implementations, the two circuit paths of FIG. 15 may share a common DAC and a common ADC and common circuit elements and/or processing device(s). The top circuit path 103 may be the force path and the bottom circuit path 189 may be the return path, as described with respect to FIG. 5. The common DAC may power LED being tested by needles 102 as described with respect to FIG. 5. The common ADC may measure the voltage and/or current across the LED being tested by needles 102 as also described with respect to FIG. 5.

Referring back to FIG. 8, chuck 99 defines a test site for the wafer. Wafer 104 resides on chuck 99 during test. Chuck 99 may be configured to hold wafer 104 to the chuck surface using vacuum, for example, or using mechanical devices, such as a clamp. As was the case with mount 15, chuck 99 may include one or more motors 109 that are controllable to move the chuck to cause the wafer to move relative to probe head 82 in the directions of arrow 110 and/or in the direction perpendicular to arrows 110 in order to align successive linear rows of LEDs to the needles on probe head 82 and to a light detector for testing. Accordingly, in this example, during testing, the probe head remains stationary while the wafer moves. In some implementations, the test assembly, and thus the probe head, may move in the directions of arrows 110 the wafer and chuck may remain stationary.

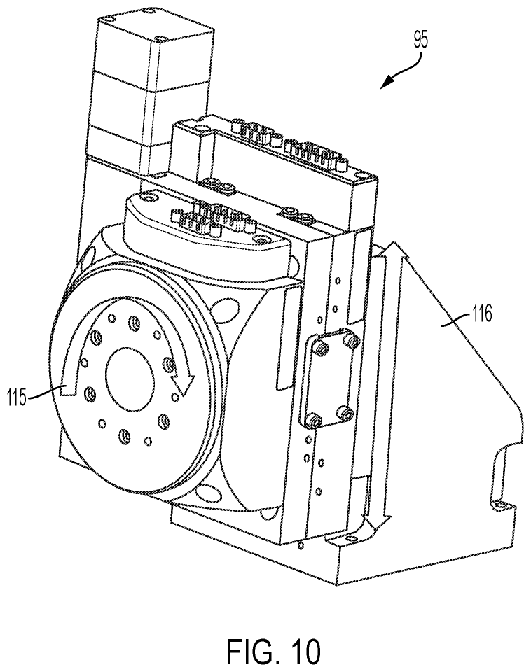

In addition to electrical connections, probe head 82, interposer 84, flexible circuit 87, top stiffener 86, bottom stiffener 86, interposer 89, and backplane 90 are physically and mechanically connected to test head 93, either directly or indirectly, such that movement of probe head 90 causes movement of test assembly 81. Thus, test head 93 controls movement of test assembly 81. Test head 93 includes stiffener 92 and mechanics 95 to enable rotational and translational motion of the test assembly. The mechanics 95 include rotational stage 115 configured to rotate test assembly 81 around axis 112. Examples of rotation around axis 112 include, but are not limited to, ±90°, ±80°, ±70°, ±60°, ±50°, ±40°, ±30°, ±20°, ±10°, ±5°, ±3°, ±2°, or ±1°. Rotation may be performed to ensure that all of the needles on probe head 82 to make electrical connections to LEDs on wafer 104. Mechanics 95 also includes translational stage 116 a configured to implement Z-axis translational motion in the direction of arrows 114 to enable needles on probe head 82 to make electrical connections to LEDs on wafer 104 or to move needles on probe head 82 away from wafer 104, thereby breaking any electrical connections. FIG. 10 shows an example implementation of one or more motors and/or actuators that are configured to implement mechanics 95. The motor(s) and/or actuators includes a rotational stage 115 that is computer-controlled to implement the rotation and a translational stage 116 that is computer controlled to implement the translation. A control system, such as control system 18 described herein, may control operation of motor(s) and/or actuators/mechanics 95.

Referring back to FIG. 8, test system 80 also includes a light detector 101, which may have the same structure and function as light detector 11 described herein, to measure the illumination of the LEDs under test and to provide information about that illumination to the one or more processing devices that are configured, e.g., programmed, to determine whether LEDs have passed or failed testing or whether the LEDs have performance deemed unacceptable, such as a QE below a predefined value, and/or to bin or sort the LEDs based on performance.

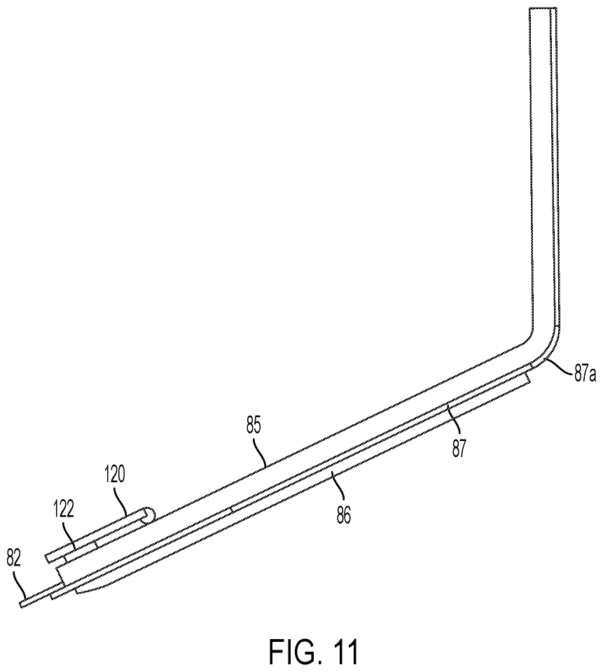

Referring also to FIG. 11, test assembly 81 also may include a top stiffener 85 and a bottom stiffener 86. Top stiffener 85 and bottom stiffener 86 provide support and structure to test assembly 80. In this example, parts of probe head 82, interposer 84, and flexible circuit 87 are sandwiched between top stiffener 85 and bottom stiffener 86. Flexible circuit 87 may be attached to top stiffener 85 using an adhesive or mechanical structure such as a clamp so that portion 87a of flexible circuit 87 that extends beyond bottom stiffener 86 remains in place. In this example, bottom stiffener 86 may be or include flat plate or the like that attaches to top stiffener 85, with parts of probe head 82, interposer 84, and flexible circuit 87 between top stiffener 85 and bottom stiffener 86.

Top stiffener 85 is bent at an angle relative to a test site holding wafer 104 and test head 93. The angle relative to test head 93 may be an obtuse angle of between 90° and 180°. For example, angle 110 (FIG. 8) may be at 110°, 115°, 120°, 125°, 130°, and so forth. Angle 111 relative to a test site holding wafer 104 may be an oblique angle that is less than 90°, e.g., 60°, 50°, 40°, 30°, 20°, and so forth. Top stiffener 85 is angled in this manner to reduce the chances of probe head 82 blocking light detector 101 from receiving light from LEDs on wafer 104, as described above and to keep the bottom stiffener 86 from hitting the wafer. For example, probe head 82, or a portion thereof, does not block an optical path between LEDs under test on wafer 104 and light detector 101 or blocks an amount that is small enough to still allow light detector 101 to detect light from the LEDs.

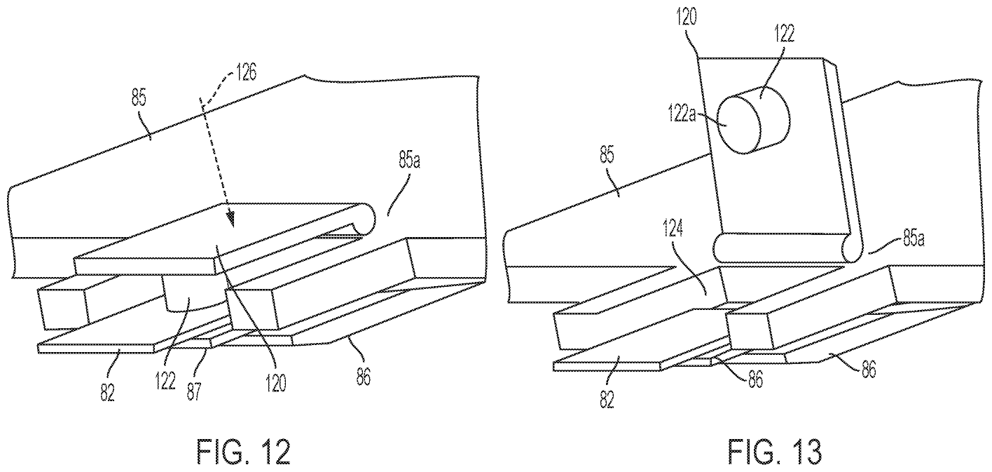

Top stiffener 85 also includes a cover 120 and a compression mechanism 122 for loading and unloading probe heads into the test assembly. More specifically as shown in FIGS. 11 to 13, cover 120 is hinged to move between an open position shown in FIG. 13 and a closed position shown in FIGS. 11 and 12. In the open position, the cover may be at an angle greater than 0° relative to the surface 85a of top stiffener 85—for example, such an angle may be 60°, 70°, 80°, 90°, and so forth, to enable access to probe head 82 in a precision slot 124. More specifically, the open position exposes slot 124 of the test assembly 81 configured to hold probe head 82 and interposer 84 (not shown in FIG. 13). In the closed position of FIGS. 11 and 12, cover 120 may be at an angle of about 0° relative to the surface 85a of top stiffener to cover probe head 82. The closed position covers a slot of the test assembly configured to hold the probe head. Slot 124 may contain alignment features, such as edges, pins, marks, or the like, which may align to complementary alignment features on the probe head and/or interposer, to ensure that the interposer is aligned to the flexible circuit when in slot 124 and to ensure that that the probe head is aligned to the interposer when in slot 124.

As shown in FIGS. 12 and 13, compression mechanism 122 is a structure that contacts probe head 82. In this example, compression mechanism 122 is a cylinder having a flat surface; however, compression mechanism 122 may have any appropriate structure—for example, it may be cubical or irregularly shaped. In some implementations, compression mechanism may be made of hard material such as metal or plastic. In some implementations, compression mechanism may have a pliable element at an end 122a thereof that contacts the probe head. The pliable element at end 122a, or end 122a itself, may be made of rubber, soft plastic, or other pliable dielectric material to prevent damage to the probe head and to prevent inadvertent electrical short circuits when cover 120 contacts the probe head.

During operation, downward force in the direction of arrow 126 (FIG. 12) generally perpendicular to cover 120 forces compression mechanism 122 against probe head 82, thereby holding the probe head in place during testing. To remove or replace the probe head, cover 120 may be opened, as shown in FIG. 13, leaving probe head 82 exposed within test assembly 81. Opening and closing cover 120 may be computer-controlled, e.g., opening and closing may be automated by the control system. In addition, the control system may control the amount of force that cover 120 applies to the compression mechanism which, in turn, is applied to the probe head. The amount of force applied should be sufficient to establish electrical connections between conductive pads 106 on probe head 82 and electrical contacts 147 and interposer 84, and between electrical contacts 154 on interposer 84 and electrical contacts 151 on flexible circuit 87 (FIG. 15) without causing damage to these or other components of test assembly 81. For example, the amount of force may be on the order of single-digit Newtons of force, tens of Newtons of force, or more depending upon the construction of the probe head and the interposer.

Referring back to FIG. 8, robot 96 is controllable to move along gantry 97 between locations of trays 100 and test assembly 81, in particular at least to a location where robot 96 can access probe head 82 when cover 120 is open. In this example, robot 96 includes an extendible and retractable robotic arm to enable the robot to access the contents of trays 100 and slot 124 (FIG. 13) containing probe head 82 and interposer 84. Robot 96 may also include an vacuum tip (suction cup) 96a at an end thereof. Suction may be applied through vacuum tip 96a to pick-up an interposer or a probe head from a tray or slot, and may be released or reversed to place the interposer or probe head in the slot or tray, respectively. Robot 96 may be controlled by a control system, such as control system 18 (FIG. 1). In some implementations, robot 96 and gantry 97 may be replaced with a robotic arm such as robotic arm 13 of FIG. 1. In such implementations, rather than including a gripper, the robotic arm includes a vacuum tip like 96a to pick-and-place an interposer and, separately, a probe head as described above.

In this example, one or more trays 100a may be for probe heads and one or more trays 100b may be for interposers. For example, compartments in trays 100b may contain probe heads that can be switched-out for probe head 82 in test assembly 81. For example, compartments in trays 100a may contain interposers that can be switched-out for interposer 84 in test assembly 81. Trays 100b and 100a may also contain empty compartments to hold probe head 82 and interposer 84, respectively.

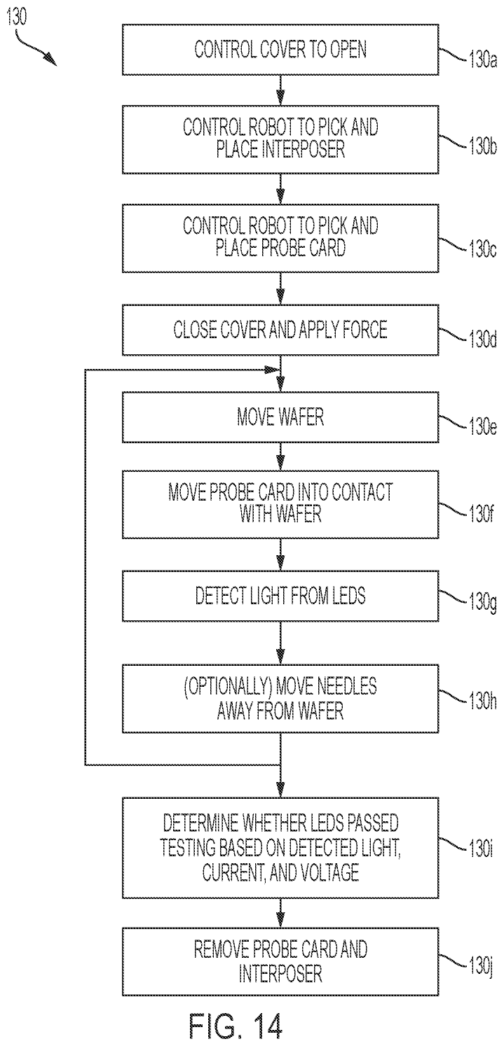

FIG. 14 shows example operations included in an example process 130 for testing a wafer containing LEDs using test system 80. Process 130 may be performed in whole or part by a control system, such as control system 18, controlling the components of the test system. In this example, process 130 starts with test assembly 81 far enough away from wafer 104 in the test site so that, when probe head 82 is installed in the test assembly, its needles 102 do not contact wafer 104.

Process 130 includes controlling (130a) cover 120 to open, thereby exposing slot 124. Process 130 includes controlling (130b) robot 96 to pick-up an interposer 84 and to place the interposer in slot 124. The interposer that is selected may be for use only with a specific probe head. For example, the interposer and corresponding probe head may have matching electrical contact configurations. So, whichever probe head is to be used for testing may determine which interposer is selected. Operations to control (130b) the robot may include controlling robot 96 to move to tray 100a to pick-up the interposer, applying suction to tip 96a to pick-up the interposer, controlling robot 96 to move to a location where slot 124 is accessible to the robot, and placing the interposer into the slot by releasing the suction or applying positive pressure (e.g., forced air) to the interposer via tip 96a.

Process 130 includes controlling (130c) robot 96 to pick-up a probe head 82 and to place the probe head in slot 124 on top of interposer 84 in slot 124. Operations to control (130c) the robot may include controlling robot 96 to move to tray 100b to pick-up the probe head, applying suction to tip 96a to pick-up the probe head, controlling robot 96 to move to a location where slot 124 is accessible to the robot, and placing the probe head 82 into the slot and on top of the interposer that is already in the slot by releasing the suction or applying positive pressure (e.g., forced air) to the probe head via tip 96.

Process 130 includes controlling (130d) cover 120 to close and applying an appropriate amount of force to cause electrical connections to be made between the probe head, the interposer, and the flexible circuit.

Wafer 20 containing LEDs to test is moved (130e) into position, e.g., by controlling chuck 99 to move in a direction of arrows 110. Test head 93 moves (130f) probe head 82 into contact with wafer 104 so that needles 102 on the probe head contact LED anode and cathode terminals in a linear array of LEDs on wafer 104 and create electrical connections to each LED, as described herein. In some implementations, test assembly 81 includes a force gauge in physical contact with the probe head, which operates as described herein, to enable the control system to regulate the amount of force applied to the needles to ensure that too much or too little force is not applied to the needles during testing. Process 130 may control test head 93 to move probe head 82 into contact with wafer 104 by controlling mechanics 95 (FIG. 10), such as one or more motors and/or actuators, to move the test assembly 81 rotationally and/or translationally relative to wafer 104.

Needles 102 on the probe head contact LED anode and cathode terminals on the wafer to create electrical connections to each diode, which causes electrical current to pass through each LED, thereby illuminating the LED in whole or in part. During testing, each LED may be turned on and then off at a specific programmed rate by increasing applied current over time. The amount of current and voltage applied over time may be obtained over the signal path or electrical circuit formed by probe needles 102, interposer 84, flexible circuit 87, interposer 89, backplane 90, and one or more circuit cards 91. The amount of current and voltage may be digitized and the resulting digital data captured to create a voltage-current (V-I) curve for each LED that is tested. In some implementations, each circuit card 91 may contain one or more processing devices 172 to create the V-I curve and to transmit the V-I curve to the control system. In some implementations, the circuit cards 91 may transmit digital data corresponding to the LED measurements to the control system and the control system may create the V-I curve using that digital data. Also, while each LED is illuminated, light detector 101 detects (130g) the light and reports the detected information to the control system or circuit card(s) along with an indication of which LED was illuminated.

Once test information has been obtained from a linear array of LEDs, probe head 82, and thus needles 102, may be controlled to move away (130h) from wafer 104 so that needles break contact with the LEDs. This operation is optional and, in some implementations, probe head 82 does not move. Thereafter, operations 130e to 130h may be repeated until test data is obtained for all linear rows of LEDs on the wafer. After the test data has been obtained, control system 18 analyzes the test data, including the detected light, as described above to determine (130i) which LEDs pass testing and which LEDs failed testing. After testing is completed, the probe head and the interposer may be removed (130j) from slot 124 as described herein and may be replaced with a different probe head and a different interposer.

In some implementations, the same probe head and interposer may be used to test an entire wafer 104. In some implementations, the probe head and interposer may be replaced during testing of a wafer 104 such that a single wafer may be tested using more than one probe head and interposer and/or more than one wafer per probe head.

Although described in the context of LEDs, the probe head and test system described herein may be used to test any type of current-controlled light-emitting element, and may be scaled to test devices of any size.

All or part of the example test systems and example processes described in this specification and their various modifications may be configured or controlled at least in part by one or more computers such as control system 18 using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected by a network.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

In the description and claims provided herein, the adjectives “first”, “second”, “third”, and the like do not designate priority or order unless context suggests otherwise. Instead, these adjectives may be used solely to differentiate the nouns that they modify.

Any mechanical or electrical connection herein may include a direct physical connection or an indirect physical connection that includes one or more intervening components. A connection between two electrically conductive components is an electrical connection unless context suggests otherwise.

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A probe head comprising:
probe needles that are electrically conductive and configured to create electrical connections to conductive pads on light emitting diodes (LEDs) on a wafer under test;
power supplies to power the LEDs;
multimeters to measure at least one of a voltage across or a current through individual ones of the LEDs; and
micro-electromechanical (MEM) switches configured to create, for each of the LEDs, an electrical connection between ones of the probe needles and both a power supply and a multimeter to cause the power supply to power the LED while the multimeter measures the at least one of the voltage across or the current through, the LED.

2. The probe head of claim 1, further comprising:
one or more processing devices to control operation of the MEM switches.

3. The probe head of claim 1, wherein the probe head comprises one multimeter and one power supply for each of multiple sets of MEM switches.

4. The probe head of claim 1, wherein the MEM switches are controllable to create electrical connection at a same time in each set of MEM switches.

5. The probe head of claim 4, wherein the MEM switches are controllable to cycle through the MEM switches in each set so that, at a same time, an Nth (N≥1) MEM switch in each set creates an electrical connection between a probe needle and a power supply or a multimeter.

6. The probe head of claim 1, wherein each multimeter comprises an analog-to-digital converter (ADC) and each power supply comprises a digital-to-analog converter (DAC).

7. The probe head of claim 1, wherein the probe needles are arranged on the probe head at an oblique angle relative to a surface of the probe head.

8. The probe head of claim 1, further comprising:
electrically conductive traces electrically connected to the multimeters; and
a transceiver to interface between the electrically conductive traces and a communication conduit for connecting the probe head to an external device.

9. The probe head of claim 1, wherein the probe head comprises a substrate; and
wherein the probe head further comprises a coupling attached to the substrate, the coupling comprising a magnetically-attracted material.

10. The probe head of claim 9, wherein the coupling comprises a metal plate.

11. The probe head of claim 9, wherein the coupling comprises alignment pins to align to a structure that magnetically attracts the coupling.

12. The probe head of claim 1, further comprising:
a flange configured for connection to a gripper.

13. The probe head of claim 1, wherein the LEDS comprise micro-LEDs or nano-LEDs.

14. A test system comprising:
a light detector arranged above a test site containing a wafer comprising light emitting diodes (LEDs), the light detector to detect light emitted from the LEDs;
a probe head arranged above the wafer so as not to block a path of light between at least some of the LEDs and the light detector, the probe head to detect voltage across, and current through, individual ones of the LEDs; and
a computing system to determine a quantum efficiency of each of the individual ones of the LEDs, where the quantum efficiency of an LED is based on the light detected from the LED, the voltage across the LED, and the current through the LED;
wherein the probe head comprises:
probe needles that are electrically conductive and configured to create electrical connections to the LEDs;
power supplies to power the LEDs;
multimeters to measure at last one of a voltage across or a current through individual ones of the LEDs; and
micro-electromechanical (MEM) switches configured to create, for each of the LEDs, an electrical connection between ones of the probe needles and both a power supply and a multimeter to cause the power supply to power the LED while the multimeter measures at least one of a voltage across or a current through the LED.

15. The test system of claim 14, further comprising:
a mount to hold the wafer during testing; and
a motor to move the mount to cause the wafer to move relative to the probe head and the light detector in order to align successive sets of LEDs to the probe head and the light detector for testing.

16. The test system of claim 14, further comprising:
a prober to hold the probe head during testing; and
a force gauge physically connected between the probe head and the prober, the force gauge being configured to measure an amount of force applied by the probe needles to the wafer.

17. The test system of claim 16, wherein the probe head comprises a substrate;
wherein the probe head further comprises a coupling attached to the substrate, the coupling comprising a magnetically-attracted material; and
wherein the test system further comprises a magnet connected to the force gauge, the magnet to magnetically attract the coupling.

18. The test system of claim 17, wherein the magnet comprises an electromagnet that is controllable by the computing system to conduct current when the probe head is within a predefined proximity of the force gauge.

19. The test system of claim 18, further comprising:
a robotic arm;
a detector to detect a magnetic connection to the force gauge, the detector to output a signal to the computing system in response to detecting the magnetic connection;
wherein the computing system is configured to control the robotic arm, based on the signal from the detector, to move the wafer to or from a storage unit.

20. The test system of claim 14, wherein the probe head comprises:
one or more processing devices to control operation of the MEM switches, the one or more processing devices being in communication with the computing system to receive instructions from the computing system for controlling operation of the MEM switches.

21. The test system of claim 14, wherein the probe head comprises one multimeter and one power supply for each of multiple sets of MEM switches.

22. The test system of claim 14, wherein the MEM switches are controllable to create one electrical connection at a same time in each set of MEM switches.

23. The test system of claim 22, wherein the MEM switches are controllable to cycle through the MEM switches in each set so that, at a same time, an Nth (N≥1) MEM switch in each set creates an electrical connection between ones of the probe needles and both a power supply and a multimeter.

24. The test system of claim 14, wherein each multimeter comprises an analog-to-digital converter (ADC) and each power supply comprises a digital-to-analog converter (DAC).

25. The test system of claim 14, wherein the probe needles are arranged on the probe head at an oblique angle relative to a surface of the probe head.

26. The test system of claim 14, wherein the probe head comprises:
electrically conductive traces electrically connected to the multimeters; and
a transceiver to interface between the electrically conductive traces and a communication conduit that is part of a communication connection between the probe head and the computing system.

27. The test system of claim 14, wherein the LEDS comprise micro-LEDs or nano-LEDs.

28. The test system of claim 14, wherein the probe head comprises a device configured to communicate, to the computing system, information about the probe head.

29. The test system of claim 28, wherein the device comprises a memory and wherein the information comprises an identity or a condition of the probe head.

30. A test system comprising:
a probe head comprising probe needles that are electrically conductive and configured to create electrical connections to light emitting diodes (LEDs) on a wafer under test;
a structure configured to hold the probe head at an oblique angle relative to a test site containing the wafer under test, the structure comprising a cover that is movable between an open position and a closed position where, in the open position, a slot configured to hold the probe head is exposed and, in the closed position, the slot is covered; and
robotics configured to move the probe head into, and out of, the slot.

31. The test system of claim 30, wherein the probe head comprises first electrically conductive conduits and first electrical contacts, the first electrically conductive conduits being between the probe needles and the first electrical contacts, the first electrical contacts being at a first pitch; and
wherein the test system further comprises an interposer, the interposer comprising second electrically conductive conduits and second electrical contacts, the second electrically conductive conduits being electrically connected between the first electrical contacts and the second electrical contacts at a second pitch.

32. The test system of claim 31, wherein the robotics is configured to move the interposer into, and out of, the slot.

33. The test system of claim 31, wherein the test system further comprises a flexible circuit, the flexible circuit comprising third electrically conductive conduits and third electrical contacts, the third electrically conductive conduits being electrically connected between the second electrical contacts and the third electrical contacts, the third electrical contacts being at a third pitch that is greater than the second pitch;
wherein the interposer is a first interposer; and
wherein the test system further comprises a second interposer, the second interposer comprising fourth electrically conductive conduits and fourth electrical contacts, the fourth electrically conductive conduits being electrically connected between the third electrical contacts and the fourth electrical contacts.

34. The test system of claim 33, further comprising:
one or more circuit cards comprising at least one of passive electronics or active electronics to process signals from the probe needles; and
a backplane electrically connected to the second interposer, the backplane electrically connecting the second interposer to one or more circuit cards, the backplane comprising fifth electrically conductive conduits and fifth electrical contacts, the fifth electrically conductive conduits being electrically connected between the fourth electrical contacts and the fifth electrical contacts, the fifth electrical contacts being at a pitch that is a same as or greater than the third pitch.

35. The test system of claim 33, wherein processing the signals comprises determining whether LEDs associated with the probe needles passed or failed testing.

36. The test system of claim 30, further comprising:
a test assembly comprising the structure; and
one or more motors or actuators to implement movement of the test assembly relative to the wafer.

37. The test system of claim 36, wherein the one or more motors or actuators are configured to at least one of: (i) rotate the test assembly relative to the wafer, or (ii) move the test assembly translationally relative to the wafer.

38. The test system of claim 26, further comprising:
a probe head, the test assembly being connected to the probe head and the probe head being controlled by the motors.

39. The test system of claim 30, wherein the cover comprises a compression mechanism having a surface configured to contact a top of the probe head.

40. The test system of claim 31, further comprising:
a light detector arranged above the test site containing the wafer under test, the light detector to detect light emitted from the LEDs.
